(19) United States
(12) Patent Application Publication
(10) Pub. No.: US 2010/0271828 A1
(43) Pub. Date: Oct. 28, 2010

(54) LIGHT-EMITTING DEVICE AND METHOD FOR ITS DESIGN

(75) Inventors: Johannes Petrus Maria Ansems, Eindhoven (NL); Christoph Gerard August Hoelen, Eindhoven (NL); Lingli Wang, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/993,056

(22) PCT Filed: Jun. 1, 2006
(86) PCT No.: PCT/IB06/51748

§ 371 Date: Dec. 19, 2007

(30) Foreign Application Priority Data
Jun. 23, 2005 (EP) 05105611.7

(51) Int. Cl. F21V 13/04; H01L 33/60; G06F 17/50

(52) U.S. Cl. 362/308; 257/98; 703/1; 257/100; 257/E33.059; 257/E33.067

(57) ABSTRACT

A small and bright light-emitting device, comprising an outer boundary lens surface and at least one LED, is achieved by carefully choosing the inclination of each surface portion of the outer lens surface with respect to the chip size of the light source. The inclination of the surface portions are chosen such that the lens provides an optimal weighing between size and light efficiency.

The present invention relates to optical systems for light-emitting diodes, and in particular to a light-emitting device comprising a light-emitting element including a light-emitting diode (LED) and a lens in optical contact with the element and arranged to receive light originating from the element. The invention also relates to a method for designing such a lens.

Light-emitting diodes (LEDs) are a relatively old technology (1970s) that has advanced from use in numeric displays and indicator lights to a range of new applications including use in LCD back panel lighting, information signs, accent lights, traffic lights, outdoor lighting and fiber optic data transmission.

LEDs offer benefits such as small size, long lamp life, low heat output, energy efficiency and durability. They also allow design flexibility in color changing, dimming and distribution by combining different LEDs into desired shapes, colors, sizes and lumen packages.

A LED normally emits light of a predetermined wavelength when a sufficient voltage is applied across the active layer. The LED is typically included in a light-emitting element, which may also include additional components, such as a color conversion layer. In most applications it is important that the light-emitting element is bright and light efficient, and usually it is desired that the light is emitted in predetermined direction within a predetermined solid angle. Advantageously, a suitable primary optic or a lens is provided on top of the light-emitting surface, in an attempt to meet these requirements. Additionally, the lens will protect the light emitting diode surface and make the LED more robust.

In a first case, the primary optics for the LED is not very carefully designed, rather e.g. intrinsic properties of the lens material, such as its surface tension, determines the shape of the lens. Typically, a fluid lens material is applied on top of the light emitting surface and left to cure.

In a second case, a more careful design of the lens is provided; an example is found in GB 1 586 188. This British patent specification describes how the lens is designed by computing a separate radius of curvature for different portions of the lens along an axis normal to, and centered at, the light emitting surface of the lens.

It is an object of the present invention to provide a light emitting diode device and an optimized lens design, which provides a light efficient optical system and a minimized thermo-mechanical stress of the primary optics.

The invention is based on an insight that it is possible to achieve a small and bright light emitting diode device with high light extraction by use of a new design of the primary optics. Said primary optics is arranged to receive light emitted from a light-emitting surface, and the design is related to the size of the light emitting surface and the difference in refractive indices between the material of the primary optics and the medium outside said primary optics.

According to a first aspect thereof, the present invention provides a light emitting device comprising a light emitting element having an effective light emitting surface with an effective diameter D_{E} and a lens in optical contact with said surface and arranged to receive light originating from said light emitting element, wherein an outer boundary surface of the lens is curved such that, in any location on the outer boundary surface, at least one edge ray from the effective light emitting surface is incident at an angle greater than or equal to θ_{c}−χ2π(1−cos θ_{c}), wherein θ_{c} equals the critical angle of total internal reflection of said lens in a given medium, and χ≦9°/sr.

In this context, the expression “in optical contact” means a direct contact of the materials involved, without an air gap in between. The lens may be the primary optics of the LED, but may alternatively be an additional optical body, arranged between the LED and the primary optics.

Note that, for the design of the lens, the largest or most outer surface of the light-emitting element that determines the light direction is relevant. This “effective light-emitting surface” may be the surface of the LED itself, or be the surface of an additional layer, such as a scatterer or wavelength converter arranged on top of the LED, if this layer redirects the light. From a LED chip surface, light is emitted in all directions and can therefore be regarded as a light-emitting surface. However, when a scattering layer is added, this scatterer redirects the light in random directions and should therefore be regarded as the light emitting surface, because especially for a strong scatterer there is no correlation any more between the direction of the light rays incident on the scatterer and the scattered light rays. This means that the effective light emitting surface area has increased, and therefore also the lens dimensions should increase to obtain the same extraction efficiency.

With respect to the present invention, the term “the effective diameter of a light emitting surface” equals the diameter of the light emitting element or the die, in case it has a circular shape. When it has another shape, e.g. square, the effective diameter of the light-emitting surface equals the diameter of a circle that has the same surface area as said die. In case of a collection of dice, the total surface area of the dice and the necessary space in between is taken as the surface area.

The term “edge ray” refers to a straight, non-refracted and non-scattered ray emitted from the border of a circular area that has the same surface area and the same point of gravity as the light source area. Moreover, the angle is calculated as the deviation from a direction orthogonal to the tangent. In other words, a light ray which is incident along a direction which is orthogonal to said outer boundary surface has an angle of incidence of 0 degrees. Consequently, a light ray, which is incident along a direction, which is almost parallel to, said outer boundary surface is said to have an angle of incidence of almost 90 degrees.

Advantageously, by designing the lens as specified above there is provided not only a light-emitting device with high light extraction, but also a light-emitting device, which has a small size. A small size is often an advantage in current miniaturized applications. As the design of the outer boundary lens surface limits the angle of incidence for said edge rays, a high light efficiency can be achieved. If the angle of incidence is too large, the light rays will be subject to significant Fresnel reflections or even total internal reflections. Hence, the light efficiency will be reduced. In order to determine if any non-refracted and non-reflected light rays originating from the light emitting surface will be reflected by the outer boundary lens surface, it is often sufficient to consider the edge rays.

Advantageously, the outer boundary surface is further curved such that, in any location on the outer boundary surface, any edge ray from said effective light emitting surface is incident at an angle equal to or smaller than θ_{c}+δ, wherein δ≦12°.

By these conditions a favorable compromise between the size of the lens and the light efficiency is achieved.

Advantageously, said light emitting surface has an effective diameter equal to D_{E}. Further the height H_{L} of said outer boundary surface is within an interval of

[D_{E}/(2*tan(θ_{c}+δ)),D_{E}/(2*tan(θ_{c}−χ27(1−cos θ_{c}))], (1)

where δ≦12° and χ≦9°/sr, and a radius R_{L} of said lens in a plane comprising the light emitting element is within a range of

[D_{E}/2,1.2*D_{E}]. (2)

The cross section of the lens in a plane comprising the optical axis of the lens is preferably contained within ellipses

$$\begin{matrix}{( \frac{x}{0.9 \cdot {R}_{L}} )}^{2} + {( \frac{y - {y}_{0}}{0.9 \cdot {H}_{L} - {y}_{0}} )}^{2} = 1 \\ and & ( 3 ) \\ {( \frac{x}{1.1 \cdot {R}_{L}} )}^{2} + {( \frac{y - {y}_{0}}{1.1 \cdot {H}_{L} - {y}_{0}} )}^{2} = 1 & ( 4 )\end{matrix}$$

wherein:
x are coordinates parallel to the surface of the light emitting element,
y are coordinates orthogonal to the surface of the light emitting element,
y₀ is a constant within the interval of [−0.1, 0.25], and
y is larger than or equal to y₀.

With respect to the present invention, the expression “a cross section smaller than a given ellipse” refers to a situation where the base radius and the height of the cross section is shorter than the base radius and the height of the ellipse, respectively. Further, when the cross section of the surface and the ellipse is arranged coaxially the cross section is contained within the ellipse.

The lens can have a refractive index such that the difference in refractive index between said lens and an outer medium surrounding said lens is between 0.2 and 0.85, preferably between 0.2 and 0.6, and even more preferably between 0.2 and 0.4. In this case, for example when the outer medium is air, the refractive index of the lens can be between 1.45 and 1.85, the height of said lens OW can be between 0.45*D_{E} and 1.2*D_{E}, the radius of said lens (R_{L}) can be between 0.55*D_{E} and 1.2*D_{E}, and the aspect ratio H_{L}/R_{L} can be in the range [0.6;1.2].

The light emitting device can further comprising a second, substantially transparent, dielectric body in optical contact with the lens. It should be noted that such a dielectric body can cover one or several light emitting devices according to the above. Preferably, the refractive index of the further dielectric body is between 1.3 and 1.6, the difference in refractive index between the lens and the further dielectric body is between 0.2 and 0.4, and the height of said lens (H_{L}) is between 0.2*D_{E} and 0.85*D_{E} and the radius of said lens (R_{L}) is between 0.5*D_{E} and 0.85*D_{E}.

Advantageously, said light emitting element comprises a color conversion element such that an efficient generation of different colors is facilitated. The color conversion element can be a phosphor layer, and is preferably coated on the surface of the LED or on the inner surface of the lens. In the latter case the color conversion element is brought in optical contact with the surface of the LED dice via a further transparent or translucent medium.

Advantageously, the light-emitting element further comprises at least two portions, which emit light within different wavelength ranges. This facilitates the generation of a predetermined desired color, by mixing the two generated colors. Alternatively, all portions of the light-emitting element emit light, which has the same color, but different portions are arranged in optical contact with different color conversion bodies, such that different colors originate from different portions of the effective light-emitting surface. For instance, blue light is emitted from the LED, two portions of the effective light-emitting surface are each provided with different fluorescent material, such that e.g. the colors red and green are generated, and one portion is left uncoated. Hence the lens is able to emit the colors red, blue and green, as well as a mix of these colors.

Advantageously, said light emitting diode device further comprises a diffusing layer arranged outside said outer boundary surface. This facilitates a mixing of the light emitted from the light-emitting element. Preferably, said diffusing layer is arranged such that it is optically separated from said outer lens surface, in order not to cause total internal reflection of any rays. If the light-emitting surface comprises two portions that emit different colors, the diffusing layer further facilitates a mixing of said colors.

Advantageously, said outer lens surface is provided with a light diffusing surface texture providing diffusion of the incident light over angles limited to χ2π(1−cos θ_{c})°.

Advantageously, said light emitting diode device is used in combination with a suitably designed reflector, which facilitates a gathering of the light emitted from said light emitting diode surface in a desired solid angle and direction. As the primary optics of the lens is smaller than conventional lenses, this facilitates the design and use of a small reflector.

Advantageously, the medium adjacent said outer boundary surface and surrounding said lens is air, and the refractive index of the lens material is between 1.4 and 1.9. Alternatively, the surrounding medium is a second optical body with a refractive index between 1 and the refractive index of said lens.

According to a second aspect thereof, the present invention provides a method of designing an cross sectional shape of an outer lens surface, comprising providing a first point, which is separated form the surface of said light emitting element by a distance equal to Dₑ/(2*tan θₛ) along a direction orthogonal to said light emitting surface, providing a first line, which is parallel to the light emitting surface and which intersects said first point, providing a second line, which intersects said first line at said first point at a first angle (α), determining a second point, on said second line, such that at least one edge ray from the light emitting surface intersects with said second line at said second point at an angle equal to θₛ, and such that no other edge ray from the light emitting surface intersects at said second point at an angle larger than θₛ, providing a third line intersecting said second line at said second point at a second angle (β), determining third point on said third line, such that at least one edge ray from the light emitting surface intersects with said third line at said third point at an angle equal to θₛ, and such that no other edge ray from the light emitting surface intersects at said third point at an angle larger than θₛ, providing a smooth curve, which intersects said first, second and third points and which represents a cross section of said outer boundary lens surface, wherein θₛ is between θ_{c}−χ2π(1−cos θ_{c}) and θ_{c}+δ, where χ≦9°/sr and δ≦12. The gist of the invention is to provide an inventive lens design, wherein the inclination of each surface portion of the lens is carefully chosen such that the lens provides an optimal weighing between size and light efficiency, for a predetermined chip size or effective diameter of the light source.

This and other aspects of the present invention will now be described in more detail, with reference to the appended drawings showing a currently preferred embodiment of the invention.

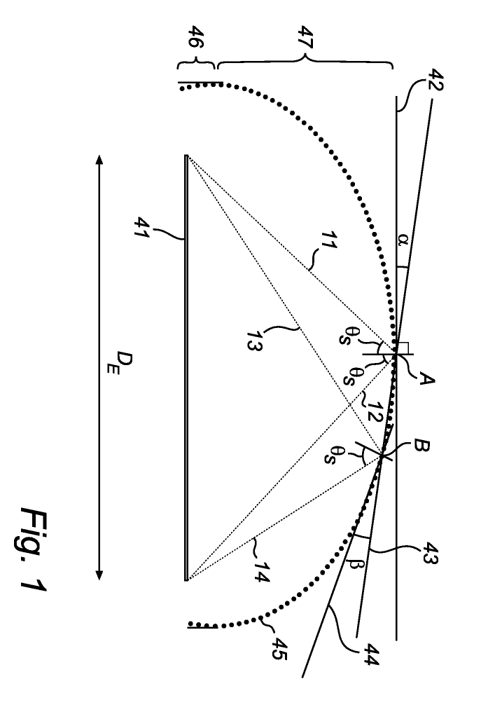

FIG. 1 schematically shows a cross sectional view of the light emitting diode device according to the invention.

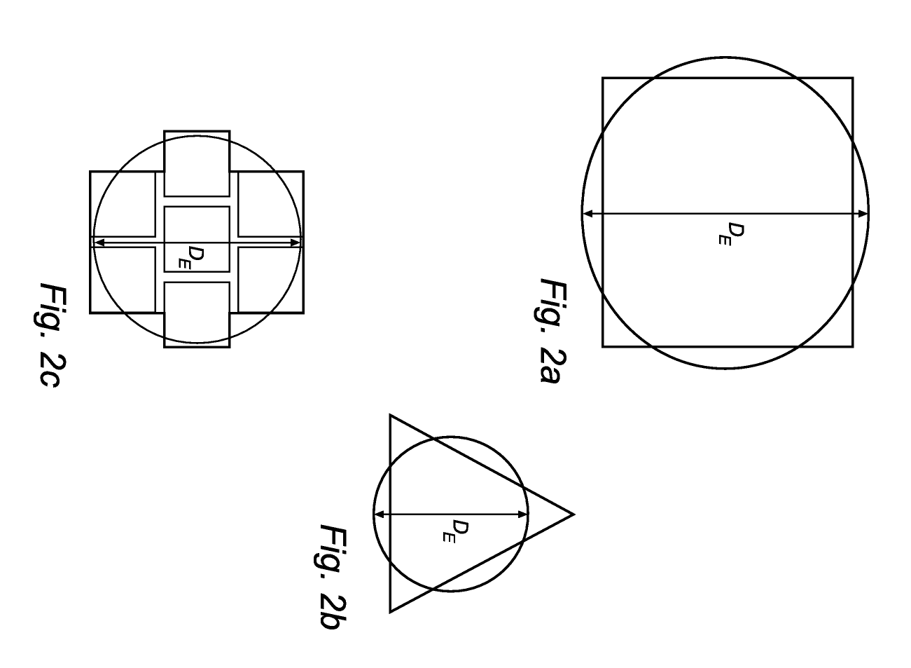

FIG. 2 schematically illustrates the definition of the term effective diameter of a light-emitting surface.

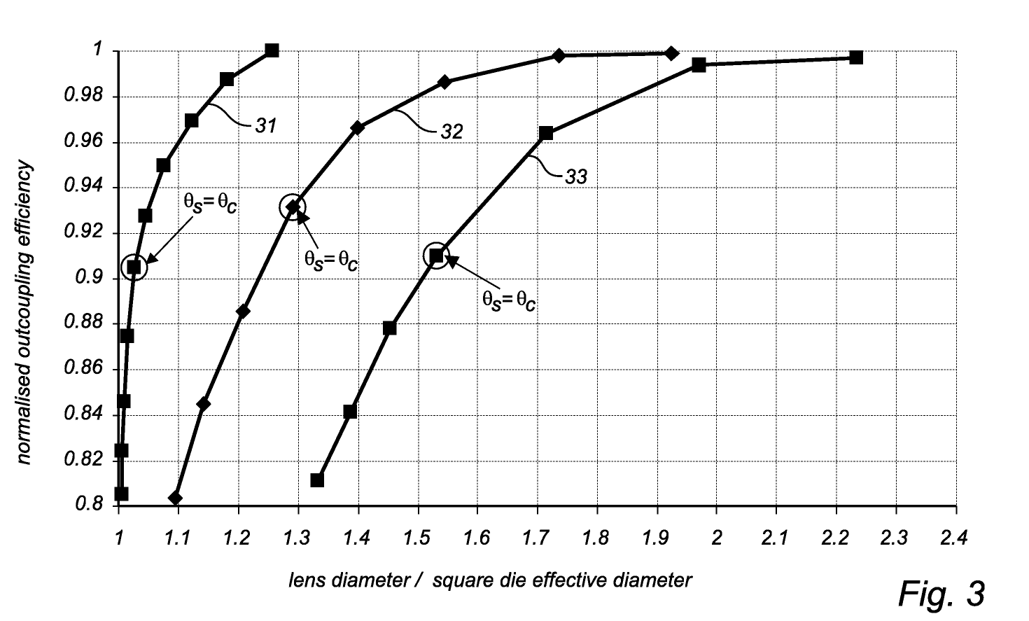

FIG. 3 schematically illustrates the light efficiency of the light emitting diode device for different values of the lens diameter normalized with the effective diameter of a square light-emitting surface.

FIG. 4 schematically illustrates a method of designing a light emitting diode device according to the invention.

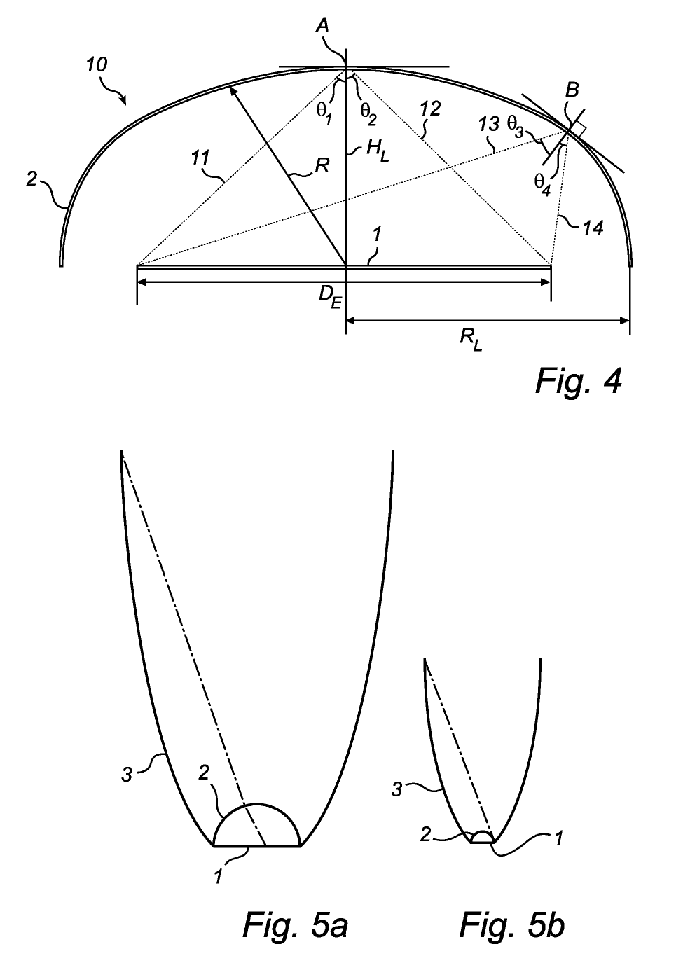

FIGS. 5a and 5b schematically illustrates that a smaller reflector can be used to obtain a certain beam width if the primary optics of the LED is smaller.

FIG. 1 schematically illustrates a method of designing an optical light-emitting device in accordance with an embodiment of the invention. In particular the design of an outer boundary surface of a lens, which lens is arranged to receive light form a light emitting surface, is shown. For simplicity the illustration is limited to the design of a cross section of said outer boundary surface.

An initial line 41 is provided, which represents the effective diameter D_{E} of the effective light emitting surface of a light emitting element, for which an outer boundary lens surface is to be designed. In other words, a curvature of the outer boundary surface is to be generated, which curvature is adjusted to the effective diameter of the light emitting element.

An angle θₛ is selected which determines the largest angle of incidence on the outer boundary surface for any straight, non-refracted and non-scattered ray from said light emitting surface. The angle is chosen carefully, as a weighting between different parameters of the lens e.g. light efficiency and size. A larger value of θₛ normally gives a smaller lens, but also a lens with reduced light efficiency. The angle θₛ preferably lies between θ_{c}−χ2π(1−cos θ_{c}) and θ_{c}+δ, wherein θ_{c} equals the critical angle of total internal reflection of the lens in a given medium, χ≦9°/sr, and wherein δ≦12°.

A first line 42, which is parallel to said initial line 41, is arranged at a distance D_{E}/2*tan(θₛ) from said initial line 41. Hence, the height H_{L} of the lens is equal to D_{E}/2*tan(θₛ). A second line 43 is provided, which intersects said first line 42 at a first point A and at a first angle α, e.g. 0.01°. Said first angle is preferably between 0.005° and 0.1°. Thereafter, a second point B is determined, where one of the edge rays 14 or 13 has an angle of incidence equal to 0, and the other edge ray has an angle of incidence smaller than, or equal to, θₛ. Further, a third line 44 is provided which intersects said second line at a second angle β at said second point B. β is preferably between 0.005° and 0.1°, and even more preferred equal to said first angle. The angles α, β are selected such that sufficient calculation fineness is achieved.

Thereafter, a third point (not shown) is determined where an edge ray intersects said third line at an angle of incidence equal to θₛ and the other edge ray has an angle of incedence smaller than, or equal to, θₛ. This is repeated until sufficiently many points have been determined, such that a smooth curve 45 representing said cross sectional lens surface, and intersecting the determined points A, B, can be provided with sufficient accuracy.

Preferably, when a provided line is almost orthogonal to the initial line 41 (e.g. inclined about 3-5° from a line normal to the initial line) no further points, arranged closer to the initial line 41 than the already determined points, are established. Instead, for this bottom portion of the lens 46, or the portion 46 of the lens which is closest to the light emitting surface, the slope of the curve 45 is made about 3° (between 0 and 5°) in order to facilitate the manufacture of the lens, as this e.g. makes the lens easier to mould. In other words, advantageously the curve 45 comprises both the bottom portion 46, which has an inclination of about 3° with respect to a direction normal to said initial line, and an upper portion 47. As described above edge rays from the light-emitting surface have a limited angle of incidence at said top portion 47 of the curve 45. This method of designing a cross section 45 of the outer boarder surface of a lens, which design corresponds to a predetermined angle θₛ and a cross sectional effective diameter D_{E} of a light emitting surface is, in relation to this invention, sometimes referred to as a specific angle lens design.

Further, if the effective light emitting surface is symmetrical, i.e. all cross sections through the center of said light emitting area have the same diameter, then a symmetrical outer lens surface can be provided as a surface of revolution by revolving said curve 45 around an axis, which is orthogonal to, and centered at, the light emitting surface.

If the light-emitting surface is non-symmetrical, a cross section of said outer boundary lens surface can be determined to a predetermined number of cross sections of said non-symmetrical light emitting surface. Thereafter a, preferably smooth, surface is determined which intersects said determined cross sections of said outer boundary lens surface. Said outer boundary surface might also approximate said determined cross sections. Alternatively, the effective diameter of the light-emitting surface is used to determine the outer boundary lens surface of a rotationally symmetric lens for a non-symmetrical light-emitting surface.

FIGS. 2a-c schematically illustrates how the effective diameter of an effective light-emitting surface is determined. Basically, the effective diameter equals the diameter of a circle enclosing the same surface as the outer contour of one or several LED dice. When the light emitting surface comprises several light emitting portions, which are separated from each other as is illustrated in FIG. 2c, the effective diameter equals the diameter of a circle which has the same surface area as the light emitting portions plus the area of the space in between the portions.

After a symmetrical lens surface has been generated according to the method described above, which has a height H_{L} and a base radius R_{L}, the surface is preferably modified slightly such that a desired optical performance is achieved with respect to e.g. the gathering of the light. In order to secure that the lens surface still provides the desired optical properties with respect to e.g. light efficiency, even after the modification, two elliptical surfaces are computed. The first elliptical surface is described by the equation (3) and the second elliptical surface is described by equation (4). Hence, the symmetrical lens surface is larger than said first elliptical surface and smaller than said second elliptical surface. The performance of the lens is normally secured if the lens surface is still larger than said first elliptical surface and smaller than said second elliptical surface even after the modification. For embodiments wherein y₀>0, the outer boundary surface of the lens is preferably given an almost vertical tangent, or a tangent which is inclined about 2-5° to the y-axis.

Alternatively, a first lens surface is generated for θₛ=θ_{c}, in accordance with the method described above. The lens surface is thereafter scaled, while keeping its proportions constant with respect to e.g. lens height H_{L} and base radius R_{L}, such that a desired size of the lens or a desired out coupling efficiency is achieved.

FIG. 3 schematically illustrates a relationship between the selected angle θₛ, the lens size and the out coupling efficiency of the lens. The out coupling (light extraction) efficiency has been calculated by use of ray-trace simulations (in the figure the normalized out coupling efficiency is given). During the simulation a lens surface designed in accordance with the specific angle design described above was used. Three different curves are shown, representing different differences in refractive index Δn between the lens material and the outer or surrounding medium, resulting in different values for θ_{c}. A reflectivity of 75% has been assumed for the light-emitting surface as well as for the surface surrounding said LED-chip. Hence, rays reflected at the boundary surface of the lens back towards the plane with the LED chip(s) are reflected partly again by the LED chip or its near surroundings, and finally transmitted out of the lens. Values along the y-axis represent the amount of light transmitted through said lens surface relative to the amount of light emitted from the light-emitting surface. The light emitting surface was a square die and the values along the x-axis represent the ratio between the diameter of the lens D_{L}=2*R_{L} and the effective diameter of the light emitting surface. The three curves represent Δn=0.2, Δn=0.5, and Δn=0.8, and the out coupling efficiency has been calculated for angles θₛ equal to θ_{c}+10°, θ_{c}+8°, θ_{c}+6°, θ_{c}+4°, θ_{c}, θ_{c}−4°, θ_{c}−8°, θ_{c}−12°, θ_{c}−16° and θ_{c}−20° in curve 31, θ_{c}+12°, θ_{c}+8°, θ_{c}+4°, θ_{c}, θ_{c}−4°, θ_{c}−8°, θ_{c}−12° and θ_{c}−15° in curve 32, and θ_{c}+6°, θ_{c}+4°, θ_{c}+2°, θ_{c}, θ_{c}−4°, θ_{c}−8° and θ_{c}−12° in curve 33.

It is evident from FIG. 3, that the smaller the value of θₛ the larger the out coupling efficiency, and vice versa. Further, the larger the diameter of the lens the higher the out coupling efficiency of the lens, for a given effective diameter of the light emitting surface and a lens construction according to the specific angle lens design.

For glass with a refractive index of 1.5, surrounded by air, the critical angle θ_{c} equals approximately 42°. A lens made of a ceramic e.g. sapphire, having a refractive index of approximately 1.8 and surrounded by air, has a critical angle approximately equal to 34°. If a light ray is incident on a lens-to-air interface, the refractive index of the lens is 1.5, and the angle of incidence is decreased from θ_{c} (the angle of incidence where Total Internal Reflection (TIR) occurs, i.e., where 100% of the light is reflected) to an angle, which is θ_{c}−3.6°, the Fresnel reflections are reduced to about 15%. Moreover, in the exact same situation, except the refractive index of the lens is 1.8, the Fresnel reflections are decreased from 100% to 15% if the angle of incidence is decreased from θ_{c} to an angle which is θ_{c}−4.1°. This means that the average angle of incidence of light, emitted from the light emitting surface, on the outer boundary surface of the lens is preferably smaller than the critical angle. The lens design criterion based on a specific angle θₛ relates to this aspect. By choosing θₛ between θ_{c}−χ*2π(1−cos θ_{c}) and θ_{c}+δ, where χ and δ are carefully chosen constants, an efficient system can be designed. θ_{c}−χ*2π(1−cos θ_{c}) is a general expression, where a predetermined value of χ gives about the same out coupling efficiency for most combinations of lens materials and surrounding medium.

In other words, θₛ is chosen carefully. The larger θₛ is made, the more light is lost due to Fresnel reflections, i.e. an increased loss of light results. A value below the critical angle can be chosen to further decrease the losses due to Fresnel reflections (i.e., in absence of total internal reflection). Light losses up to about 20% may be accepted, which correspond to θₛ=θ_{c}+δ=θ_{c}+12°. Preferably, θₛ is smaller than θ_{c}+3°, which equals a light loss of about 10%. It has been found that the values of δ are essentially independent of the selected combination lens material and surrounding medium, at least for values of δ smaller than 15°.

FIG. 4 schematically shows a cross sectional view of a light emitting diode device 10 according to one embodiment of the invention. Said device comprises a light-emitting element 1, having an effective light-emitting surface. The effective diameter of said light emitting surface is D_{E}. In front of the light emitting element a lens is arranged in optical contact with the light-emitting surface of the light-emitting element. In this embodiment the lens is made of glass having a refractive index of 1.5. The outer boundary surface 2 of the lens surrounding the light-emitting surface 1 illustrates the inventive design. The lens 2 is arranged for receiving light from said light emitting element 1. The outer surface of said lens is designed by considering the angle of incidence θ₁, θ₂, θ₃, θ₄ at which unrefracted light, emitted from said light emitting surface, intersects with a tangent to the outer surface of the lens 2, in accordance with the description in relation to FIG. 1. As is readily seen from FIG. 4, it is sufficient to considerer the angle of incidence of a pair of edge rays 11, 12; 13, 14 of the light emitting surface, in order to know the largest angles of incidence at a certain point A;B on a cross section of the lens surface for all unrefracted rays from said light emitting surface.

At an arbitrary point B on the outer boundary surface of the lens 2, there is at least one edge ray 14 which angle of incidence is within said first interval, and no edge ray from the effective source area which angle of incidence is larger than θₛ.

According to the invention, if the lens is surrounded by air and has a refractive index equal to 1.5, then the height H₁, of the lens should be 0.56*D_{E}/2 for a specific angle design with θₛ=θ_{c}. Additionally, the base radius of the lens R_{L} should be 0.65*D_{E}/2 for a design at the critical angle. Further, a lens shaped according to the design corresponds with a light extraction efficiency or out coupling efficiency of about 93%. Moreover, for a specific angle design with θₛ=θ_{c}, where the lens is surrounded by air and has a refractive index equal to 1.78, the height H₁, of the lens should be 0.74*D_{E}/2, and the base radius of the lens R_{L} should be 0.77*D_{E}/2. A lens according to this design corresponds to a light extraction efficiency of 91%.

Moreover, in order to facilitate color conversion the light emitting diode surface can be provided with a wavelength converting body, e.g. a layer comprising fluorescent phosphor. As an example, phosphor particles may be embedded in an organic or inorganic, transparent or translucent, dielectric material. Alternatively, the phosphor can be applied in the form of a fully ceramic body.

To couple out light from LED dice efficiently, optical contact with an optical body (e.g. lens or collimator, e.g. epoxy molded over the dice, or possibly via an optical encapsulating material between the dice and the optical body) is required. Color variable light sources can be constructed by mounting multiple dice emitting at least two different wavelengths closely together, resulting in a small source where much of the color mixing already takes place in the source. A small light emitting surface area is required for minimization of the optics that are needed to create a particular light beam, e.g. a 10 degrees spot light beam shape or a 30 degrees flood light beam shape. Multiple dice, emitting light of approximately the same wavelength, can be mounted closely together to create a light source of higher power. Mounting these dice as compact as possible results in light emitting area's that approximate a circular area. To minimize thermo mechanical stress and to minimize the size of the optics needed to shape a light beam, the dimensions of an optical dome mounted on top of, or over, the dice should be minimized.

FIGS. 5a and 5b schematically illustrate that a smaller reflector can be used if the primary optics of the LED is smaller. In FIG. 5a a chip 1 having the effective length of 1 mm is provided with a spherical lens 2 having a diameter of 5.6 mm and a refractive index of 1.5. Further, the optical system, comprising the light emitting surface and the lens, is arranged in a reflector 3 such that the resulting optical system is a 2*20° etendue limited system. The height of the reflector is 26.7 mm and its diameter is 18.3 mm.

FIG. 5b schematically illustrates another 2*20° etendue limited system provided with a light emitting device according to the invention. The chip 1 has an effective length of 1 mm and the lens 2 has a diameter of 1.5 mm and a refractive index of 1.5. The reflector is substantially smaller than the one illustrated in FIG. 3b, the height being 12.5 mm and the diameter 7.46 mm.

A person skilled in the art will given the above described conditions be able to select suitable light sources, color conversion bodies and lens material. He also realizes that the present invention by no means is limited to the preferred embodiments described above. On the contrary, many modifications and variations are possible within the scope of the appended claims. For example, other combinations of lens material and surrounding medium can be used such as a sapphire dome in a silicone gel.

1-25. (canceled)

26. A light emitting device comprising:
a light emitting element comprising a light emitting diode (LED), said element having an effective light emitting surface (1) with an effective diameter D_{E}, and
a lens (2) in optical contact with said surface and arranged to receive light originating from said light emitting element,
wherein an outer boundary surface of said lens is curved such that, in any location on the outer boundary surface, at least one edge ray (11-14) from said effective light emitting surface is incident at an angle (θ₁-θ₄) greater than or equal to θ_{c}−χ2π(1−cos θ_{c}), wherein θ_{c} equals the critical angle of total internal reflection of said lens in a given medium, and χ≦9°/sr, and
wherein said outer boundary surface (2) is curved such that, in any location on the outer boundary surface, any edge ray (11-14) from said effective light emitting surface (1) is incident at an angle less than or equal to θ_{c}+δ, wherein δ≦12°.

27. A light emitting device according to claim 26, wherein a height H_{L} of said lens is within a range of:
[D_{E}/(2*tan(θ_{c}+δ)),D_{E}/(2*tan(θ_{c}−χ2π(1−cos θ_{c}))],
where δ≦12° and χ≦9°/sr, and a radius R_{L}, of said lens in a plane comprising the light emitting element is within a range of:
[D_{E}/2,1.2*D_{E}].

28. A light emitting device according to claim 26, wherein χ≦6°/sr.

29. A light emitting device according to claim 26, wherein χ≦3°/sr.

30. A light emitting device according to claim 26 wherein δ≦7.5°.

31. A light emitting device according to claim 26 wherein δ≦3°.

32. A light emitting device according to claim 31, wherein a cross section of said lens in a plane comprising the optical axis of the lens is larger than the ellipse described by the equation:
$${( \frac{x}{0.9 \cdot {R}_{L}} )}^{2} + {( \frac{y - {y}_{0}}{0.9 \cdot {H}_{L} - {y}_{0}} )}^{2} = 1$$
and smaller than the ellipse described by the equation:
$${( \frac{x}{1.1 \cdot {R}_{L}} )}^{2} + {( \frac{y - {y}_{0}}{1.1 \cdot {H}_{L} - {y}_{0}} )}^{2} = 1$$
wherein:
x are coordinates parallel to the surface of the light emitting element (1),
y are coordinates orthogonal to the surface of the light emitting element (1),
y₀ is a constant within the interval of [−0.1, 0.25], and
y is larger than or equal to y₀.

33. The device according to claim 27 wherein the aspect ratio of the lens (H_{L}/R_{L}) is in the range between 0.4 and 1.2.

34. A light emitting device according to claim 26, wherein said light emitting element further comprises a color conversion element arranged to receive light from at least a portion of said LED, to alter the wavelength of at least part of said received light and to direct at least part of said received and wavelength converted light towards said lens.

35. A light emitting device according to claim 34, wherein said color conversion element is a phosphor containing layer, preferably coated on said LED.

36. A light emitting device according to claim 26, wherein said lens (2) has a refractive index such that the difference in refractive index between said lens and an outer medium surrounding said lens is between 0.2 and 0.85, preferably between 0.2 and 0.6, and even more preferably between 0.2 and 0.4.

37. A light emitting device according to claim 36, wherein the refractive index of said lens (2) is between 1.45 and 1.85, the height of said lens (H_{L}) is between 0.45*D_{E} and 1.2*D_{E}, the radius of said lens (R_{L}) is between 0.55*D_{E} and 1.2*D_{E}, and the aspect ratio H_{L}/R_{L} is in the range [0.6;1.2].

38. A light emitting device according to claim 26, further comprising a second, substantially transparent, dielectric body in optical contact with the lens, wherein the refractive index of the further dielectric body is between 1.3 and 1.6, the difference in refractive index between the lens and the further dielectric body is between 0.2 and 0.4, and wherein the height of said lens (H_{L}) is between 0.2*D_{E} and 0.85*D_{E} and the radius of said lens (R_{L}) is between 0.5*D_{E} and 0.85*D_{E}.

39. A light emitting device according to claim 26, wherein said light emitting element comprises at least two LEDs, which emit light within different wavelength ranges.

40. A light emitting device according to claim 26, further comprising a diffusing layer arranged outside said outer boundary surface.

41. A light emitting device according to claim 40, wherein said diffusing layer is optically separated from said outer boundary surface.

42. An optical system comprising a reflector and a light emitting device according to claim 26.

43. An optical system according to claim 42, wherein said reflector is a dielectric collimator, that reflects light based on total internal reflection.

44. A method of providing a lens comprising the steps of:
providing a first point (A), which is separated from the surface of said light emitting element by a distance equal to Dₑ/(2*tan θₛ) along a direction orthogonal to said light emitting surface, wherein D_{E} is an effective diameter of a surface (41) of a light emitting element;
providing a first line (42), which is parallel to the light emitting surface and which intersects said first point;
providing a second line (43), which intersects said first line at said first point at a first angle (α);
determining a second point (B), on said second line, such that at least one edge ray (14) from the light emitting surface intersects with said second line at said second point at an angle equal to θₛ, and such that no other edge ray from the light emitting surface intersects at said second point at an angle larger than θₛ,
providing a third line (44) intersecting said second line at said second point at a second angle (β);
determining third point on said third line, such that at least one edge ray from the light emitting surface intersects with said third line at said third point at an angle equal to θₛ, and such that no other edge ray from the light emitting surface intersects at said third point at an angle larger than θₛ,
providing a smooth curve (45), which intersects said first, second and third points and which represents a cross section of said outer boundary lens surface, and
providing an outer surface of a lens having a cross sectional shape of said smooth curve,
wherein θₛ is between θ_{c}−χ2π(1−cos θ_{c}) and θ_{c}+δ, where χ≦9°/sr and δ≦12.

45. A method according to claim 44, wherein χ≦6°/sr and δ≦7.5°.

46. A method according to claim 45, wherein χ≦3°/sr and δ≦3°.

47. A method according to claim 44, wherein said steps of providing an additional line and determining a further point is repeated a predetermined number of times.

48. A method according to claim 44, wherein said first and second angles (α, β) are within the range of 0.005° and 0.1°, preferably within the range of 0.01° and 0.05°.

49. A method according to claim 46, which further comprises the step of scaling said provided smooth curve such that its proportions is kept constant.
